(19) United States
(12) Patent Application Publication
(10) Pub. No.: US 2014/0273467 A1
(43) Pub. Date: Sep. 18, 2014

(54) Polycrystalline-silicon etch with low-peroxide apm

(71) Applicant: INTERMOLECULAR INC., San Jose, CA (US)

(72) Inventor: Gregory Nowling, San Jose, CA (US)

(73) Assignee: INTERMOLECULAR INC., San Jose, CA (US)

(21) Appl. No.: 13/804,438

(22) Filed: Mar. 14, 2013

(51) Int. Cl. H01L 21/3213; C09K 13/00; H01L 21/311

(52) U.S. Cl. CPC H01L 21/32134; H01L 21/31111; C09K 13/00
USPC 438/702; 438/753; 252/79.1

(57) ABSTRACT

Polycrystalline silicon (poly-Si) can be thoroughly removed without significant effect on adjacent oxides by an aqueous solution of ammonium hydroxide with smaller concentrations of hydrogen peroxide than are normally used in ammonia-peroxide mixture (APM) formulations used for cleaning. The etching selectivity of poly-Si relative to oxides can be widely tuned by varying the hydrogen-peroxide concentration. Compared to other formulations used to remove poly-Si dummy gates in logic-node fabrication, such as TMAH, these aqueous solutions are less hazardous to workers and the environment.

### TECHNICAL FIELD

The present disclosure relates generally to methods for forming semiconductor devices using wet etch technologies.

### BACKGROUND

Advanced semiconductor devices continue to shrink in size. This increases the density and performance of the devices. Additional benefits of increased manufacturing efficiency and lower costs are also realized. As the size of the devices shrink, the processing sequences become more challenging.

One of the critical elements of the semiconductor devices is the gate structure. The design, materials, size, and process sequence details of the gate structure determine attributes such as power consumption, speed, and reliability. As the size of the semiconductor devices has continued to shrink, the gate dielectric material has changed from silicon dioxide to high k dielectric material such as hafnium oxide and the like. Additionally, the conductive materials used as gate electrodes have been selected to have the proper work function for n-type and p-type devices.

Traditionally, the manufacturing of semiconductor devices has employed a “gate first” manufacturing process sequence wherein the gate structure is formed and the remaining elements are formed subsequent to the gate structure formation. The gate structure can be damaged during some of the subsequent processing steps and this has limited the process window (e.g. temperature) of some of the subsequent processing steps. An alternate manufacturing process sequence known as “gate last” or “replacement gate” forms the gate structure and the surrounding elements using a “dummy gate” that is used as a structural surrogate for the gate during the manufacturing process. The dummy gate structure is then removed and the final gate materials are deposited. This allows a broader process window during the manufacturing and does not expose the final gate materials to potential damage during the processing.

The removal of the dummy gate structure is a critical step in this manufacturing process sequence. Ideally, the dummy gate material is removed completely but adjacent features are left intact.

A common etchant used to remove the poly-silicon is tetramethylammonium hydroxide (TMAH). Although effective at removing poly-silicon, the TMAH process is sensitive to issues such as the pre-doping levels of the poly-silicon. The TMAH is ineffective at removing silicon nitride and silicon oxide, so if silicon nitride or oxide residues are present or if a native silicon oxide film has formed, the poly-silicon removal will be incomplete. Additionally, the TMAH etch process is sensitive to the crystal orientation of the poly-silicon. Therefore, the etch may be non-uniform

Polycrystalline silicon (“poly-Si”) is a popular dummy-gate material. Often, the surrounding features are oxide materials. Therefore, a need exists for a way to expediently remove poly-Si without unacceptable effects on neighboring oxides. Preferably, the materials used would be inexpensive and not sufficiently hazardous to require very specialized handling or disposal. Those skilled in the art will recognize that such a method could find application, not only in replacement-gate fabrication, but in any process where poly-Si needs to be selectively removed from the vicinity of oxide materials.

### SUMMARY

The following summary of the disclosure is not intended to particularly identify key or critical elements or to delineate a scope of invention. Its sole purpose is to present some concepts in a simplified form as a prelude to the more detailed description that is presented below.

Poly-Si is removed using one or more embodiments of an aqueous solution of ammonium hydroxide and hydrogen peroxide (“ammonia-peroxide mixture” or “APM”). The ratios of hydrogen peroxide to ammonium hydroxide in these solutions are preferably 1:1000-1:10—much smaller than is typical of the more common APM formulations used for cleaning. Ratios of water to ammonium hydroxide are preferably 1:1 to 20:1.

In some embodiments, substrates are exposed to the aqueous solution at temperatures between about 20-80 C. Processing times are typically between about 1-60 minutes for typical present-day dummy gates, but depend on the composition of the aqueous solution, the processing temperature, the amount of poly-Si that needs to be removed, and the composition and size of the other features that need to be left intact.

### BRIEF DESCRIPTION OF THE DRAWINGS

FIGS. 1A-1F conceptually illustrate a process making use of poly-Si etching.

FIG. 2 is a graph showing a dependence of the etching rate and selectivity of the aqueous solution on the concentration ratio of hydrogen peroxide to ammonium hydroxide.

FIG. 3 presents a flow chart describing methods according to some embodiments.

FIG. 4 illustrates a simple device schematic according to some embodiments.

FIG. 5 illustrates a simple device schematic according to some embodiments.

FIG. 6 shows an example of an embodiment where a dummy gate oxide was removed.

### DETAILED DESCRIPTION

Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

FIGS. 1A-1F conceptually illustrate a process making use of poly-Si etching. In FIG. 1A, a substrate 101 (which may or may not have an oxide layer) is coated with poly-Si layer 102A. In FIG. 1B, the poly-Si layer is partially removed, leaving poly-Si ridge or bump 102B. In FIG. 1C, ridge or bump 102B is overcoated with dielectric 103C (which may include an oxide and may not be as smooth on top as in the illustration). In FIG. 1D, the dielectric is partially removed (for example by chemical-mechanical polishing or “CMP”), exposing poly-Si ridge or bump 102B and leaving remaining dielectric structure 103D surrounding ridge or bump 102B. In FIG. 1E, substrate 101 is exposed to poly-Si etchant 104. FIG. 1E illustrates the ideal result: all the poly-Si is removed, leaving a clean, sharp-cornered opening 105E with intact substrate 101 as its bottom surface and intact dielectric structures 103D as its side walls. Here, a corner is substantially sharp if its radius is less than 1/10 of the length of the shortest intersecting line segment (e.g., the wall or floor of a hole, trench, or other opening.

FIG. 1F illustrates a non-ideal result typical of a sub-optimal etchant. Some poly-Si 102F is left in the corners. Because of this, any material put into opening 105F will only make partial contact with substrate 101 and dielectric structures 103F.

In addition, in FIG. 1F the etchant removed a noticeable portion of dielectric structures 103F as well as the poly-Si, reducing their thickness from their previous level 106. In some applications, this is an undesirable result because it wastes material or adds uncertainty to a critical dielectric thickness. However, there may be other applications where some removal of the dielectric is also desired, and still other applications where equal etch rates or even oxide-selective etching is desired.

A range of aqueous APM (ammonia-peroxide mixture) etchant solutions have been shown to completely etch poly-Si without unacceptable impact on surrounding dielectric oxides. The ratios of hydrogen peroxide to ammonium hydroxide in these solutions are preferably 1:1000-1:10—much smaller than is typical of the more common APM formulations used for cleaning. Ratios of water to ammonium hydroxide are preferably 1:1 to 20:1.

FIG. 2 is a graph showing how the etching rate and selectivity of the aqueous solution depends on the concentration ratio of hydrogen peroxide to ammonium hydroxide. Here, the ratio of ammonium hydroxide to water was 1:5 and the process temperature was 65 C. The poly-Si etch rate shown in curve 201 is very sensitive to small amounts of hydrogen peroxide. The fastest etch rate, >3000 Å/min, was for a solution with no peroxide at all. However, some applications prefer slower etch rates because they are easier to control and less sensitive to small differences in other parameters such as temperature and exposure time. Ratios of hydrogen peroxide to ammonium hydroxide from 1:1000 to 1:10 etch the poly-Si faster than either a trench oxide (curve 202, also referred to as an “interlayer dielectric” or ILD) or a gate oxide (curve 203). Ranges between about 1:50 and 1:20 etch poly-Si about 10× faster than they etch many oxides. Ratios from near 1:4 to near 1:1 etch the ILD faster than the poly-Si and the poly-Si faster than the gate oxide. Ratios above 1:1 etch the ILD and the gate oxide faster than the poly-Si.

One explanation for these results is that the hydrogen peroxide oxidizes the poly-Si while the ammonium hydroxide etches it; thus, the more hydrogen peroxide is mixed into the aqueous solution, the more the poly-Si acts like a more etch-resistant oxide.

FIG. 3 presents a flow chart describing manufacturing methods according to some embodiments. FIG. 4 illustrates a portion of a semiconductor device formed by the manufacturing methods of FIG. 3. The device may be part of an integrated circuit such as a logic circuit or a memory circuit. Those skilled in the art will understand that the circuit will generally include other device elements such as resistors, capacitors, inductors, fuses, P-channel field effect transistors (PFETs), N-channel field effect transistors (NFETs), metal-oxide-semiconductor field effect transistors (MOSFETs), complimentary metal-oxide-semiconductor field effect transistors (CMOSs), or other suitable device elements. All of these device elements and circuits are manufactured using complex processing sequences consisting of hundreds of steps. For clarity, only those steps associated with the present disclosure are described in detail.

In the first step, 300, of the method described in FIG. 3, a substrate is provided that includes a gate structure. An exemplary region and gate structure, 400, are illustrated in FIG. 4. At this point, the substrate has already completed many previous processing steps. The portion of the device illustrated in FIG. 4 includes a portion of the substrate, 402, and isolation regions, 404. The elements identified in FIG. 4 are symmetric, so only the elements on the left side of the figure have been identified. The substrate as described herein is typically silicon, but may also be any one of silicon-germanium, germanium, silicon carbide, gallium arsenide, indium phosphide, etc. The isolation regions, 404, serve to isolate this device from neighboring devices (not shown). The isolation regions are typically silicon oxide, silicon nitride, silicon oxy-nitride, other suitable insulating materials, or combinations thereof. The isolation regions are formed using well known techniques such as LOCal Oxidation of Silicon (LOCOS) or Shallow Trench Isolation (STI).

The portion of the device illustrated in FIG. 4 also includes doped regions, 406, formed in the substrate. The doped regions form the source/drain regions of the device and may be lightly doped or heavily doped. The doped regions may be doped with n-type dopants or p-type dopants.

The portion of the device illustrated in FIG. 4 also includes interlayer dielectric (ILD) layer, 408. Examples of materials suitable for ILD layer, 408, include silicon oxide, silicon nitride, silicon oxy-nitride, low-k dielectric materials, other suitable dielectric materials, or combinations thereof. The ILD layer may be a single layer or may be formed from multiple layers.

The portion of the device illustrated in FIG. 4 also includes a gate structure that includes a dummy gate, 412 (often made of poly-Si), a gate oxide layer, 414, and spacers, 410. The gate structure may include other layers (not shown) such as interfacial layers, barrier layers, liner layers, etc. The processes used to form gate structures include photolithography, etching, deposition, etc. The dummy gate, 412, and gate oxide layer, 414, cover the underlying substrate during the formation of the spacers, 410, doped regions, 406, ILD layers, 408, and other structures within the device.

In some embodiments, gate oxide layer 414 is a dummy gate oxide that is eventually removed and replaced with the high-dielectric-constant (“high-k”) oxide layer of the finished device. In other embodiments, gate oxide layer 414 is a high-k oxide layer that will be present in the finished device.

At this point in the manufacturing of the device, the dummy gate 412 has served its purpose and needs to be removed. In the next step, 302, of the method of FIG. 3, portions of the gate structure (e.g. dummy gate 412 and, if appropriate, gate-oxide layer 414) are removed to form openings in the gate structure.

FIG. 5 illustrates an exemplary region and gate structure 500 after removing the poly-Si dummy gate using an APM etchant tuned to etch poly-Si much faster than gate oxide 414. If the gate oxide is similar to the gate oxide that generated curve 203 in FIG. 2, a ratio of less than 1/10 as much hydrogen peroxide as ammonium hydroxide would be convenient for producing this result. Opening 516 has been formed, with spacers 410 of the interlayer dielectric 408 as walls and gate oxide 414 as a floor. Substrate 402, isolation regions 404, doped regions 406, ILD layer 408, spacers 410, and gate-oxide layer 414 are substantially unaltered.

In some embodiments, the APM solution may be used to remove the poly-silicon at temperatures between 20 C and 80 C, such as between 60 C and 65 C. The time required for the APM solution to remove the poly-silicon can vary between 1 minute and 60 minutes and will depend on parameters such as APM solution concentration, APM solution temperature, poly-silicon thickness, etc. In some embodiments, time required for the APM solution to remove the poly-silicon can vary between 5 minutes and 60 minutes, such as 15 minutes, 25 minutes, or 50 minutes. After poly-Si dummy gate 412 is removed, the sample may be rinsed in deionized water. If gate oxide 414 is the high-k oxide or other oxide layer intended for incorporation in the finished device, it may be left in place.

FIG. 6 shows an example of an embodiment where gate oxide 414 was a dummy gate oxide and was removed, making a deeper opening 616 extending down to substrate 402. Typically a dummy gate oxide is removed using a dilute hydrofluoric acid solution, but in embodiments where the dummy gate oxide is more rapidly etched by ammonium hydroxide than interlayer dielectric 408 or spacer 410, an APM solution may also be used here.

In some embodiments, a thin native silicon oxide forms on top of the poly-Si dummy gate, 214. As noted previously, the etch rate of silicon oxide in the APM solution is very slow. Therefore, the thin native oxide can be removed by exposing the substrate to a dilute hydrofluoric acid solution prior to the removal of the poly-silicon. This will produce a clean, oxide free poly-silicon surface that can be removed using the APM solution described previously. Alternately, it may be possible to add a small amount of hydrofluoric acid to the APM solution. The hydrofluoric acid constituent would serve to etch the native oxide layer and allow the APM solution to remove the poly-silicon. The concentration of the hydrofluoric acid is maintained at a low level so that it does not result in significant loss of spacer or ILD layer material.

Returning to FIG. 3, the device is ready for the completion of the gate stack and the completion of the manufacture of the circuit in step 304. These steps will not be described in further detail.

Although the foregoing examples have been described in some detail for purposes of clarity of understanding, the invention is not limited to the details provided. There are many alternative ways of implementing the invention. The disclosed examples are illustrative and not restrictive. The scope is limited only by the claims and numerous alternatives, modifications, and equivalents are encompassed.

We claim:

1. A method of etching polycrystalline silicon on a substrate, the method comprising:
preparing an aqueous solution comprising ammonium hydroxide and hydrogen peroxide, where a ratio of the ammonium hydroxide to the hydrogen peroxide is within a range of about 10:1-1000:1, and
exposing the polycrystalline silicon to the aqueous solution at a temperature between about 25 C and 80 C.

2. The method of claim 1, where a ratio of water to the ammonium hydroxide in the aqueous solution is within a range of about 1:1 to 20:1.

3. The method of claim 1, where
the substrate comprises an oxide adjacent to the polycrystalline silicon, and
the aqueous solution etches the polycrystalline silicon more rapidly than the aqueous solution etches the oxide.

4. The method of claim 3, where the aqueous solution etches the polycrystalline silicon more than about 10 times as rapidly as the aqueous solution etches the oxide.

5. The method of claim 1, where the polycrystalline silicon is oxidized by the hydrogen peroxide and etched by the ammonium hydroxide.

6. The method of claim 5, where the aqueous solution forms an opening through the polycrystalline silicon into an underlying layer.

7. The method of claim 6, where a cross-section of the opening comprises a substantially sharp corner between a side wall and a bottom surface.

8. The method of claim 1, where the polycrystalline silicon is exposed to the aqueous solution for a duration between about 1-60 minutes.

9. An etchant for polycrystalline silicon, the etchant comprising:
an aqueous solution comprising ammonium hydroxide and hydrogen peroxide,
where a ratio of the ammonium hydroxide to the hydrogen peroxide is within a range of about 10:1-1000:1.

10. The etchant of claim 9, where a ratio of water to the ammonium hydroxide in the aqueous solution is within a range of about 1:1 to 20:1.

11. The etchant of claim 9, where the hydrogen peroxide oxidizes the polycrystalline silicon and the ammonium hydroxide etches the polycrystalline silicon.

12. A method of replacement-metal-gate integration, the method comprising:
depositing a gate oxide,
depositing polycrystalline silicon over the gate oxide,
selectively patterning the polycrystalline silicon to create a dummy gate,
depositing an interlayer dielectric over and around the dummy gate,
removing the interlayer dielectric from a surface of the dummy gate, and
exposing the dummy gate and the interlayer dielectric to an aqueous solution at a temperature between about 25 C and about 8° C. until the polycrystalline silicon of the dummy gate is etched away, creating an opening in the interlayer dielectric with a surface of the gate oxide comprising a bottom of the opening,
where the aqueous solution comprises ammonium hydroxide and hydrogen peroxide in a ratio between about 10:1 and 1000:1.

13. The method of claim 12, where a concentration ratio of water to the ammonium hydroxide in the aqueous solution is within a range of about 1:1 to 20:1.

14. The method of claim 12, where the aqueous solution etches the polycrystalline silicon more rapidly than the aqueous solution etches the gate oxide or the interlayer dielectric.

15. The method of claim 14, where the aqueous solution etches the polycrystalline silicon more than about 10 times as rapidly as the aqueous solution etches the gate oxide or the interlayer dielectric.

16. The method of claim 12, where exposing the dummy gate and the interlayer dielectric to the aqueous solution removes substantially all the polycrystalline silicon from the opening.

17. The method of claim 12, where the hydrogen peroxide oxidizes the polycrystalline silicon and the ammonium hydroxide etches the polycrystalline silicon.

18. The method of claim 12, where the polycrystalline silicon is exposed to the aqueous solution for a duration between about 1-60 minutes.

19. The method of claim 12, further comprising removing the gate oxide.
